(19) United States
(12) Patent Application Publication
(10) Pub. No.: US 2009/0309157 A1
(43) Pub. Date: Dec. 17, 2009

(54) MOS TYPE SEMICONDUCTOR DEVICE

(75) Inventor: Yasumasa WATANABE, Matsumoto City (JP)

Correspondence Address: ROSSI, KIMMS & McDOWELL LLP., 20609 Gordon Park Square, Suite 150, Ashburn, VA, 20147, US

(73) Assignee: FUJI ELECTRIC DEVICE TECHNOLOGY CO., LTD., Tokyo (JP)

(21) Appl. No.: 12/485,798

(22) Filed: Jun. 16, 2009

(30) Foreign Application Priority Data
Jun. 16, 2008 (JP) 2008-156099
Apr. 2, 2009 (JP) 2009-090001

(51) Int. Cl. H01L 29/78

(52) U.S. Cl. 257/336; 257/E29.256; 257/E29.268

(57) ABSTRACT

A MOS type semiconductor device, in which both improvement in radiation resistance and increase in withstand voltage is achieved, includes a nitride film formed on a LOCOS film and a PBSG film formed on the nitride film. The refractive index of the nitride film is set in a range of from 2.0 to 2.1 and the thickness of the nitride film is set in a range of from 0.1 Am to 0.5 μm to thereby provide the nitride film as a semi-insulative thin film. Of electron-hole pairs produced in the LOCOS film by γ-ray irradiation, holes low in mobility are let away to a source electrode via the nitride film to thereby suppress the amount of plus fixed electric charges stored in the LOCOS film. The provision of such a three-layer structure permits improvement in radiation resistance and increase in withstand voltage.

### BACKGROUND OF THE INVENTION

The present invention relates to an MOS type semiconductor device improved in radiation resistance.

A thick separation oxide film is generally provided for element separation in an MOS type semiconductor device. An oxide film called “field oxide film”, for example, about 1 μm thick is formed in the periphery of an active portion of an element in which a main electric current flows. Generally, each of the field oxide film and the thick separation oxide film is made of an oxide film (hereinafter referred to as “LOCOS film”) formed by an LOCOS (Local Oxidation of Silicon) technique.

When such an MOS type semiconductor device is irradiated with an ionizing radiation such as a gamma (γ) ray, electron-hole pairs are produced in the LOCOS film or a gate oxide film. When a voltage is applied to the MOS type semiconductor device, the produced electrons move toward a plus electrode (drain electrode side) and the produced holes move toward a minus electrode (source electrode side) in the oxide film.

The mobility of the electrons in the oxide film is so high that the electrons move to the drain side rapidly and are pulled out from the oxide film. On the other hand, the mobility of the holes in the oxide film is so low that the holes are caught in hole traps existing in the oxide film and are accumulated as plus fixed electric charges, or the holes cut bonding in a silicon-oxide film interface to produce an interfacial level.

When the plus fixed electric charges or the interfacial level is produced, the net impurity concentration in the silicon interface varies. When the plus fixed electric charges or the interfacial level becomes very high, an accumulation layer or an inversion layer is formed in the silicon interface. As a result, there occurs a change in characteristic of the MOS type semiconductor device such as reduction in withstand voltage or increase in leakage current.

The amount of emergence of electron-hole pairs is proportional to the thickness of the oxide film. In a thin gate oxide film having a thickness not larger than 25 nm, the amount of emergency of electron-hole pairs is small. In a thick oxide film such as an LOCOS film used for the element separation oxide film or the field oxide film, the accumulated amount of plus fixed electric charges or the amount of emergence of the interfacial level is however so high that characteristic deteriorates remarkably because the thickness of the oxide film reaches 0.8 Am or larger.

FIG. 11A is a plan view showing the configuration of an important part of an MOSFET. FIG. 11B is a sectional view of important part, taken along the line Y1-Y1 in FIG. 11A. FIG. 11C is a sectional view of important part, taken along the line Y2-Y2 in FIG. 11A. Although FIG. 11A shows the case where the MOSFET is formed in a corner of a semiconductor chip 1, the MOSFET may be formed inside of the semiconductor chip 1 when the MOSFET forms an integrated circuit. In this case, a chip end portion 21 shown in FIG. 1A is provided as a boundary between this element and another element.

In FIG. 11A, a drain portion 2 is disposed in a surface portion of the semiconductor chip 1 while source portions 3 are disposed opposite to the drain portion 2. The plan view is provided for the sake of convenience of description, so that the drain portion 2 and the source portions 3 are shaped like islands. A drain electrode 13 formed in the drain portion 2 and source electrodes 12 formed in the source portions 3 are also shaped like islands. In an actual element, planar patterns of the drain portion 2 and the source portions 3 are often complicated like teeth of a comb. The island-shaped drain electrode 13 is actually often connected as one drain electrode. The island-shaped source electrodes 12 are actually often connected as one source electrode.

In FIGS. 11B and 11C, the MOSFET includes a p-type silicon substrate 4, an active portion formed on the p-type silicon substrate 4, and a separation structure portion formed on the p-type silicon substrate 4. The active portion has a low concentration p-type diffusion layer 5 (p-type well region), a low concentration n-type diffusion layer 6 (n-type offset region), high concentration n-type diffusion layers 7 and 17 (7 is an n-type source region and 17 is an n-type drain region), a high concentration p-type diffusion layer 8 (p-type contact region), an LOCOS film 9, a BPSG (Boro-Phospho Silicate Glass) film 10, a gate electrode 11, a source electrode 12, and a drain electrode 13. The separation structure portion has two-layer films, that is, an LOCOS film 18 and a BPSG film 10 formed in a chip outer circumferential portion 22.

Incidentally, the LOCOS film 9 and the LOCOS film 18 are formed at once so as to be connected to each other. The source portion 3 is made up of the high concentration p-type diffusion layer 8 and the high concentration n-type diffusion layer 7. The drain portion 2 is made up of the high concentration n-type diffusion layer 17.

FIG. 12A is a plan view showing a place of electric field concentration in the case where the element configured as shown in FIGS. 11A to 11C has not been subjected to γ-ray irradiation. FIG. 12B is a sectional view taken along the line Y1-Y1 in FIG. 12A. As a result of electric potential distribution simulation, the electric potential at a point A on a surface of a chip corner portion 23 is 30V. On the other hand, a breakdown point is in a portion B with respect to which the drain portion 2 and the source portion 3 are opposite to each other as shown in FIG. 12B. The portion B is a portion of the low concentration n-type diffusion layer 6 below the gate electrode 11. The withstand voltage (breakdown voltage) of the portion B is 163V.

FIG. 13A is a plan view showing a place of electric field concentration in the case where plus fixed electric charges of 5×10¹¹ cm² are produced in the element peripheral portion in the LOCOS film when the element configured as shown in FIGS. 11A to 11C is irradiated with γ rays. FIG. 13B is a sectional view taken along the line Y3-Y3 in FIG. 13A.

When the whole surface of the element is irradiated with γ rays, electrons in electron-hole pairs produced in the LOCOS film 18 move out of the LOCOS film 18 rapidly because the mobility of electrons is high. On the other hand, holes are trapped as plus fixed electric charges 33 in the LOCOS film 18 because the mobility of holes is low. The total number of electron-hole pairs produced in the chip corner portion 23 is large because the chip corner portion 23 has a wide area. For this reason, a large number of plus fixed electric charges 33 exist in the chip corner portion 23. To imitate this, FIGS. 13A and 13B are designed so that plus fixed electric charges 33 are produced in the element peripheral portion (chip corner portion 23).

Although it is a matter of course that plus fixed electric charges 33 are produced also in the LOCOS film 9, the total number of plus fixed electric charges 33 produced in the LOCOS film 9 is very small compared with the total number of plus fixed electric charges 33 produced in the chip corner portion 23. Accordingly, in the electric potential distribution simulation, the plus fixed electric charges 33 produced in the LOCOS film 9 are omitted.

As a result of the electric potential distribution simulation, the electric potential at a point C (corresponding to the point A in FIG. 12A) on a surface of the chip corner portion 23 shown in FIG. 13A is 47V which is higher by 17V than the electric potential without γ-ray irradiation. Moreover, the withstand voltage is reduced to 120V which is lower by 43V than the withstand voltage without γ-ray irradiation. The breakdown point is moved to a point D in a surface portion of the outer circumference of the source portion 3. It is believed that the withstand voltage is reduced because the breakdown point is moved to an end of the source portion 3 by accumulation of plus fixed electric charges 33.

Measures to solve this problem have been disclosed, for example, in JP-A-62-104158. According to JP-A-62-104158, a laminated structure having a thin oxide film (estimated to be a thin oxide film of the order of tens of nanometers) and a BPSG film is used. The BPSG film includes a large number of recombination centers and a large number of electron/hole traps. Electron-hole pairs produced by radiation are caught in the recombination centers and the electron/hole traps included in the BPSG film. For this reason, electrons and holes caught in the traps in the BPSG film offset each other to produce an electrically neutral state without occurrence of any charging phenomenon. On the other hand, the number of holes trapped in the thin oxide film is larger than the number of electrons trapped in the thin oxide film. The charging phenomenon in the thin oxide film is however negligible because the thin oxide film is so thin that the number of holes trapped in the thin oxide film is vary small on the whole.

Another MOSFET having another configuration according to the background art will be described with reference to FIGS. 14-16. FIG. 14 is a plan view showing important part of an n-type MOSFET as a constituent member of an integrated circuit. A source region 52 and a drain region 53 are disposed in an active region 51 surrounded by an LOCOS film 59. A gate region 54 is disposed straddling the active region 51. FIG. 15 is a sectional view of important part, taken along the line A-A in FIG. 14. FIG. 16 is a sectional view of important part, taken along the line B-B in FIG. 14.

The MOSFET includes a p-type silicon substrate 55, a p-type diffusion layer 56 formed on the p-type silicon substrate 55, the source region 52 as a high concentration n-type diffusion layer, the drain region 53 as a high concentration n-type diffusion layer, a middle concentration p-type diffusion layer 58 selectively formed as a surface layer of the p-type diffusion layer 56 so as to be higher in impurity concentration than the p-type diffusion layer 56 and lower in impurity concentration than the source region 52 and the drain region 53, the LOCOS film 59, a gate insulating film 60 formed on the p-type diffusion region 56 so as to be located between the source region 52 and the drain region 53, the gate electrode 54 formed on the gate insulating film 60, and a protective film 61 with which a surface is covered.

In an n-type insulated gate semiconductor element which is turned on when the gate thereof has positive polarity, holes produced in the oxide film move to the interface between the oxide film and silicon and separates H by cutting Si—H bonds. As a result, void levels in a range of from zero to bivalence are produced. When the semiconductor element is irradiated with radiation while a positive bias is applied to the gate, electric field intensity near a bird's beak of LOCOS increases so that surface inversion occurs.

Moreover, the amount of emergence of electric charges due to irradiation with radiation is proportional to the thickness of the oxide film. Because an oxide film such as HTO, BPSG, TEOS (tetraethoxysilane), etc. with a total thickness of 2 μm is deposited as a protective film on a gate end portion, it is impossible to neglect the influence of electric field from the gate end on electric charges produced in the oxide film.

In an n-type semiconductor element, a method of increasing the p-type impurity concentration under the LOCOS film 59 is effective as measures to avoid the electric field. By this method, increase in leakage current can be suppressed when the total dose quantity is not larger than about 1 kGy. Lowering of the withstand voltage is however unavoidable. When the p-type impurity concentration of the surface was about 5×10¹⁶ cm⁻³, the withstand voltage was 12.0V. When the p-type impurity concentration of the surface was about 1×10¹⁷ cm⁻³, the withstand voltage was 9.6V.

FIG. 17 is a graph showing threshold characteristic of an NMOSFET before and after irradiation with radiation using cobalt-60 as a γ-ray radiation source. The channel width and channel length of the NMOSFET are both 25 μm and the total dose quantity is 1 kGy. In FIG. 17, the curve A shows characteristic before irradiation and the curve B shows characteristic after irradiation. In the vertical axis of the graph, “E” expresses exponential notation. For example, “E-10” expresses 10⁻¹⁰.

Before γ-ray irradiation, the threshold voltage was 0.66V, the drain withstand voltage was 12.0V and the leakage current was 1.0 pA. After γ-ray irradiation, the threshold voltage was 0.60V, the leakage current was 200 nA and the drain withstand voltage was 12.0V. The threshold voltage decreased by 60 mV, and the leakage current increased by about five digits. The withstand voltage was unchanged.

Measures to improve radiation resistance have been disclosed in JP-A-62-104158. A laminated structure having a thin oxide film and a BPSG film is used. The BPSG film includes a large number of recombination centers and a large number of electron/hole traps. Because produced electron-hole pairs are caught in the recombination centers and the electron/hole traps, electric charges are hardly accumulated. Accordingly, characteristic hardly changes, so that high radiation resistance is exhibited. Moreover, a thermal oxide film about 30 nm thick is formed on the silicon interface, so that the measures are also effective in suppressing increase of leakage current.

JP-A-60-193342 describes a technique which is based on the fact that holes produced by an ionizing effect due of radiation are caught in an SiO₂ film while electrons are dominantly caught in the interface between a silicon nitride film and the SiO₂ film, and in which the SiO₂ film on a surface of an active region is removed and an SiO₂ film not thicker than 100 nm (e.g. 50 nm thick) is formed newly on the surface of the active region at a temperature not higher than 1000° C. and a silicon nitride film (e.g. 100 nm thick) is further formed thereon at a temperature of about 800° C. so that a semiconductor device excellent in radiation resistance can be produced.

JP-A-62-133726 describes a technique in which a silicon nitride film is formed on a field oxide film and a silicon oxide film is further formed on the silicon nitride film so that a semiconductor device excellent in radiation resistance can be produced.

JP-A-61-93641 describes a technique in which a silicon oxide film or phosphorous glass and a silicon nitride film are formed alternately on a thermal oxide film so that a semiconductor device excellent in radiation resistance can be produced.

JP-A-60-218850 describes a technique in which a conducting material (i.e. a good conductor such as aluminum) is mixed with an insulating layer in a transistor to thereby aggressively trap and neutralize electrons and holes produced in the insulating layer by radiation so that a semiconductor device excellent in radiation resistance can be produced.

JP-A-4-6832 describes a technique in which an amorphous silicon layer is formed in a field oxide film so that a semiconductor device excellent in radiation resistance can be produced.

JP-A-2006-222210 describes a technique in which a discontinuous thin film of carbon is interposed between an interlayer insulating film as a passivation film and a sealing resin layer as a mold resin layer to neutralize movable ions accumulated in the interface between the sealing resin layer and the interlayer insulating film through the discontinuous thin film of carbon or metal to thereby prevent the withstand voltage of an MOSFET from varying according to the movable ions.

JP-A-11-145464 describes a technique in which a protective oxide film or a protective nitride film by plasma CVD with compressive stress is formed on a protective nitride film by thermal CVD with tensile stress as a protective insulating film of a laminated structure to thereby decrease the electron/hole trap level formed by penetration of water and prevent penetration of water per se.

As described in JP-A-62-104158, radiation resistance can be improved as described above when a BPSG film is formed on a thin oxide film. It is however difficult to produce a high withstand voltage MOS type semiconductor device by combining the thin oxide film and the BPSG film. When the amount of radiation increases, it is further difficult to produce a high withstand voltage MOS type semiconductor device because electric charges produced by radiation are not trapped so that surface inversion causes a leak path.

In JP-A-60-193342, JP-A-62-133726, JP-A-61-93641, JP-A-60-218850, JP-A-4-6832 and JP-A-11-145464, there is no description about a technique in which a semi-insulative nitride film defining a refractive index, a semi-insulative thin film made of a carbon thin film not thicker than the order of nanometers, etc. is formed on an insulating film and connected to a source electrode to thereby produce a semiconductor device excellent in radiation resistance.

In JP-A-2006-222210, the discontinuous thin film is provided for the purpose of preventing plus or minus ions included in the mold resin but there is no description about removal of holes produced in the insulating film formed on the semiconductor substrate surface by irradiation with radiation.

In view of the above, it would be desirable to provide an MOS type semiconductor device in which the aforementioned problems are solved to attain improvement in radiation resistance and increase in withstand voltage.

### SUMMARY OF THE INVENTION

The invention provides a MOS type semiconductor device with improved radiation resistance and increased withstand voltage. In accordance with the invention, an MOS type semiconductor device is provided that includes an insulating film disposed on a semiconductor substrate, and a thin film disposed on the insulating film so as to be lower in resistivity than the insulating film, wherein the thin film is electrically connected to a source electrode or to both the source electrode and a drain electrode. With this configuration, electric charges produced in the insulating film by radiation can be let out rapidly via the thin film and the source electrode.

The insulating film is preferably either of an LOCOS film and a thermal oxide film. When an integrated circuit is formed, the LOCOS film is often used as the insulating film. On the other hand, when a single device requiring no micro-fabrication is formed, the thermal oxide film is often used as the insulating film.

The thin film is preferably disposed so that a source portion and a drain portion disposed on the semiconductor substrate to form the MOS type semiconductor device are surrounded by the thin film. In this manner, the source portion and the drain portion are surrounded by the thin film so that electric charges produced in the insulating film can be removed or fixed effectively.

The thin film preferably has such a resistivity that a current of 1 pA to 1 nA flows when a rating voltage of the element is applied between the source electrode and the drain electrode.

The thin film is preferably a semi-insulative thin film. Still further, the semi-insulative thin film is either of a nitride film and a film capable of producing negative fixed electric charges and has a refractive index of 2.0 to 2.1. When the semi-insulative thin film has such a refractive index, a proper resistivity can be obtained.

The thin film may also be a conductive thin film, wherein the conductive thin film is either of a carbon thin film and a high melting point metal thin film and has an average thickness of 0.1 nm to 0.5 nm. When such a very thin film is used as the conductive thin film, a high resistance value can be obtained. Preferably, the high melting point metal thin film is any one of a tungsten thin film, a titanium thin film and a chromium thin film.

Still further, a second insulating film higher in resistivity than the thin film can be preferably formed on the insulating film through the thin film.

According to the invention, an MOS type semiconductor device improved in radiation resistance can be achieved in such a manner that a separation structure portion of an MOSFET is formed as a three-layer structure in which: a LOCOS film or a thermal oxide film is provided as a first layer on a silicon interface, an electric charge easily-movable film (such as a semi-insulative thin film or a conductive thin film) is provided as a second layer and an insulating film (such as a BPSG film or a laminated film having an HTO film and a BPSG film) is provided as a third layer; and the second layer is connected to a source electrode to thereby suppress the amount of plus fixed electric charges stored in the silicon interface portion by irradiation with radiation.

Other features, advantages, aspects, embodiments, etc. of the invention will become apparent to those skilled in the art from the following detailed description of the preferred embodiments of the invention.

### BRIEF DESCRIPTION OF THE DRAWINGS

The invention has been described with reference to certain preferred embodiments thereof and the accompanying drawings, wherein:

FIGS. 1A and 1B are diagrams showing the configuration of important portion of a MOS type semiconductor device according to a first embodiment of the present invention, FIG. 1A being a plan view of important part and FIG. 1B being a sectional view of important part, taken along the line Y1-Y1 in FIG. 1A;

FIG. 2 is a sectional view showing important part of an MOS type semiconductor device according to a second embodiment of the invention;

FIG. 3 is a sectional view showing important part of an MOS type semiconductor device according to a third embodiment of the invention;

FIG. 4 is a plan view showing important part of the MOS type semiconductor device according to a fourth embodiment of the invention;

FIG. 5 is a sectional view of important part, taken along the line X-X in FIG. 4;

FIG. 6 is a sectional view of important part, taken along the line Y-Y in FIG. 4.

FIG. 7 is a graph showing the threshold characteristic of the NMOSFET before and after irradiation with radiation using cobalt-60 as a γ-ray source;

FIG. 8 is a plan view showing important part of an MOS type semiconductor device according to a fifth embodiment of the invention;

FIG. 9 is a plan view of important part showing a modification of FIG. 8;

FIG. 10 is a sectional view showing important part of an MOS type semiconductor device according to a sixth embodiment of the invention;

FIGS. 11A to 11C are diagrams showing the configuration of important part of an MOSFET, FIG. 11A being a plan view of important part, FIG. 11B being a sectional view of important part, taken along the line Y1-Y1 in FIG. 11A, and FIG. 11C being a sectional view of important part, taken along the line Y2-Y2 in FIG. 11A.

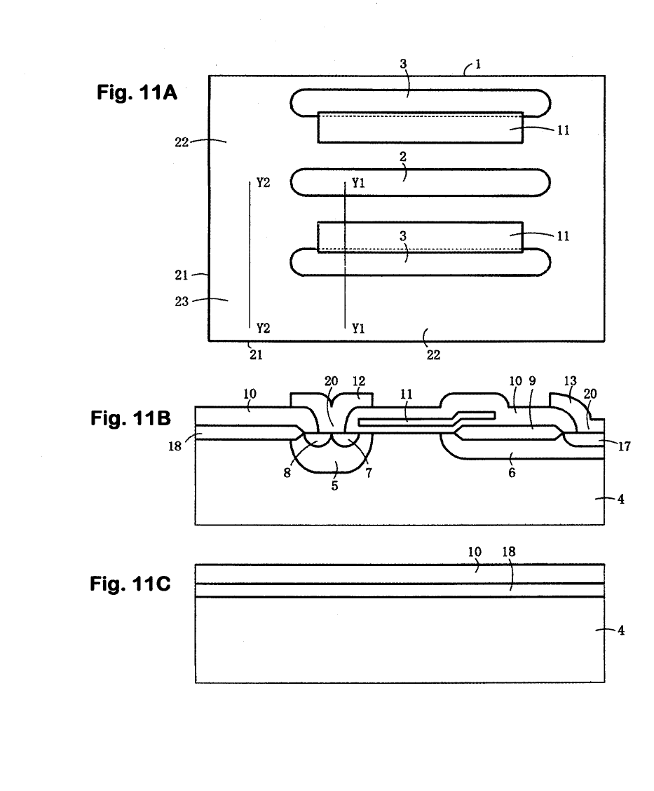

FIGS. 12A and 12B are diagrams showing a place of electric field concentration in the case where element configured as shown in FIGS. 11A to 11C has not been subjected to γ-ray irradiation, FIG. 12A being a plan view, and FIG. 12B being a sectional view taken along the line Y1-Y1 in FIG. 12A;

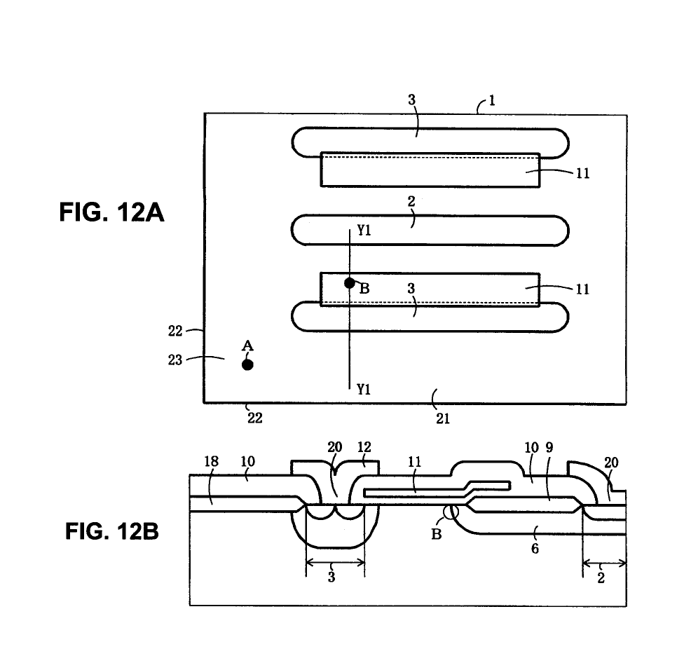

FIGS. 13A and 13B are diagrams showing a place of electric field concentration in the case where plus fixed electric charges of 5×10¹¹ cm⁻² are produced in the element peripheral portion in the LOCOS film when the element configured as shown in FIGS. 11A to 11C is irradiated with γ rays, FIG. 13A being a plan view and FIG. 13B being a sectional view taken along the line Y3-Y3 in FIG. 13A;

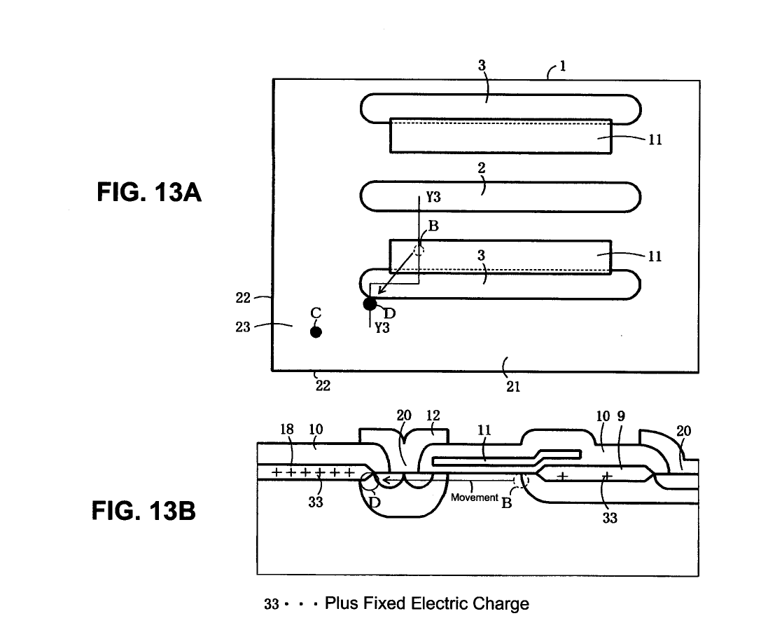

FIG. 14 is a plan view showing important part of an n-type MOSFET as a constituent member of an integrated circuit;

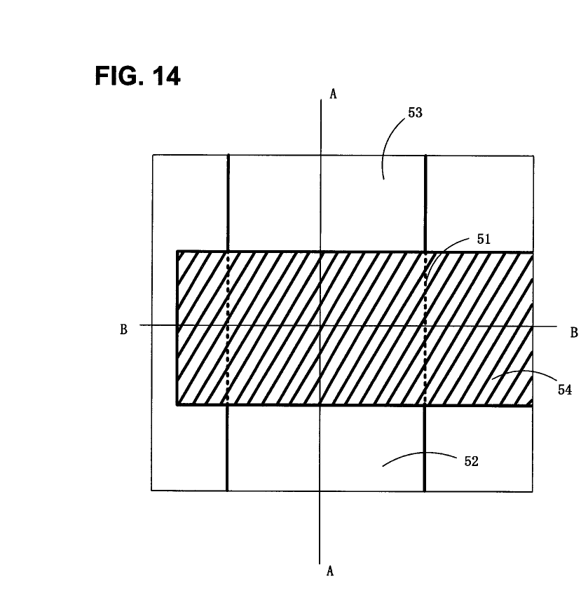

FIG. 15 is a sectional view of important part, taken along the line A-A in FIG. 14;

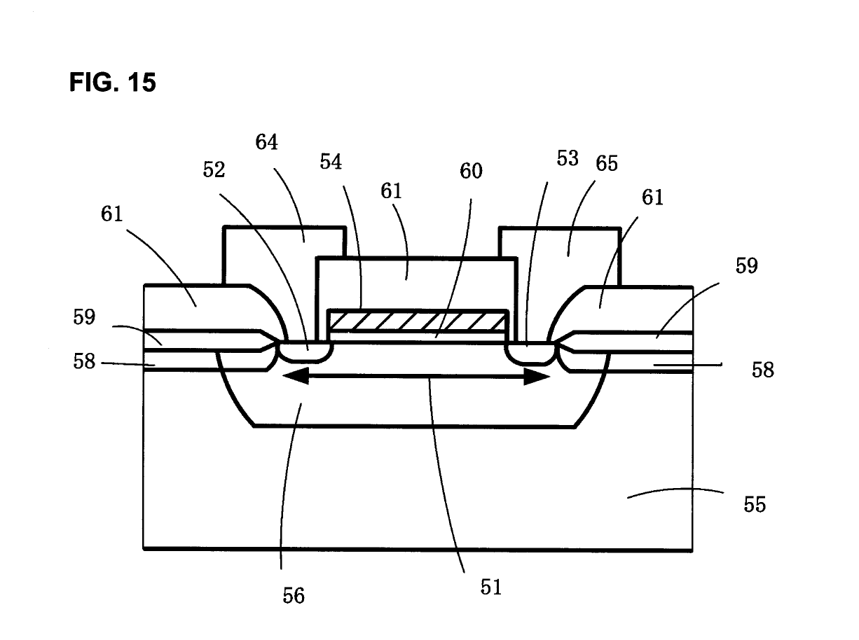

FIG. 16 is a sectional view of important part, taken along the line B-B in FIG. 14; and

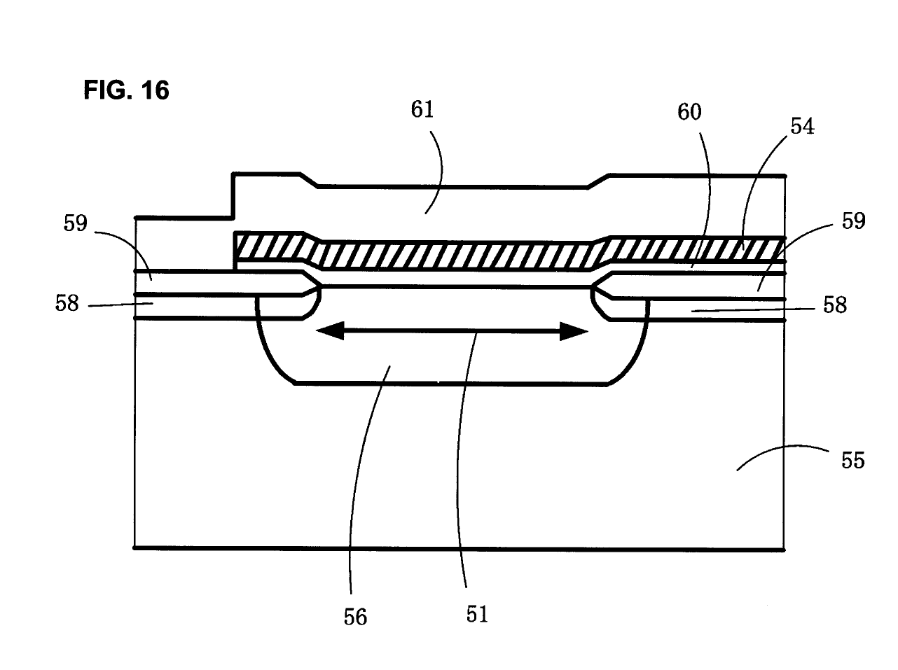

FIG. 17 is a graph showing threshold characteristic of an NMOSFET before and after irradiation with radiation using cobalt-60 as a γ-ray radiation source.

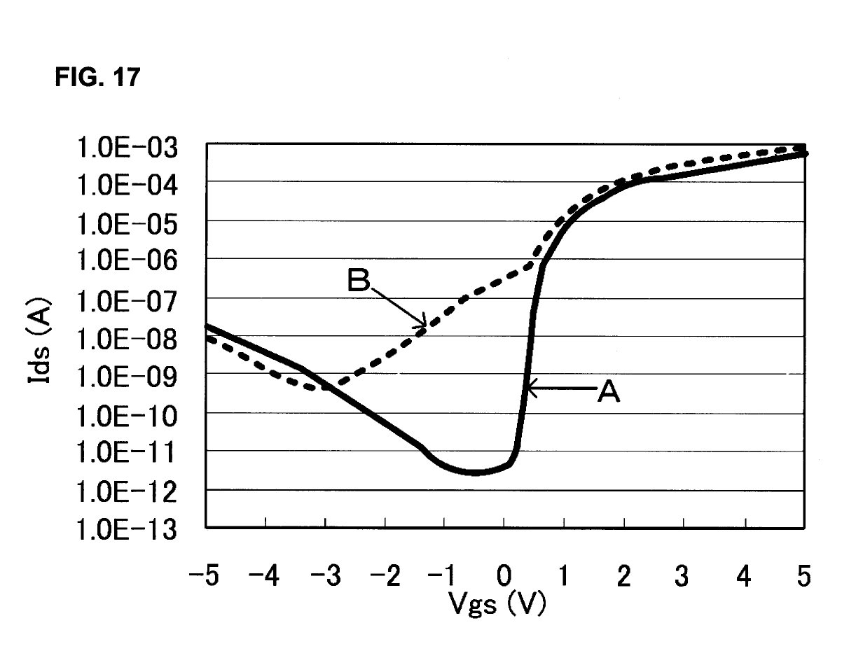

### DETAILED DESCRIPTION OF THE PREFERRED EMBODIMENTS

Modes for carrying out the invention will be described below in connection with the following embodiments. In the following description, the same parts as those in the structure according to the background art are referred to by the same numerals.

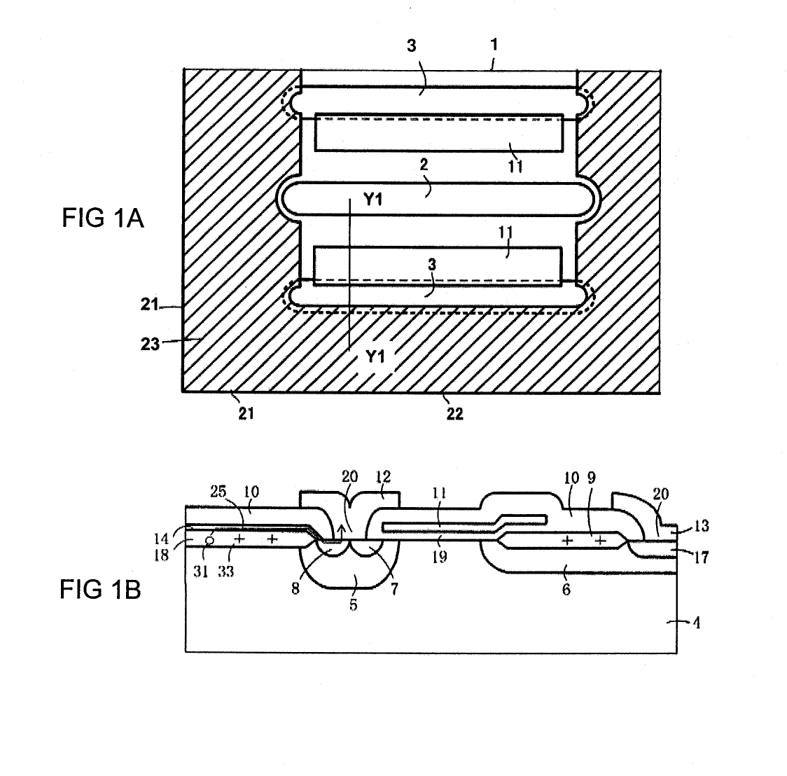

FIG. 1A is a plan view showing the configuration of important part of an MOS type semiconductor device according to a first embodiment of the invention. FIG. 1B is a sectional view of important part, taken along the line Y1-Y1 in FIG. 1A. An MOSFET is taken as an example of the MOS type semiconductor device. The point of difference of this structure from the structure according to the background art lies in that a nitride film 14 is formed as a semi-insulative thin film on an LOCOS film 18 and electrically connected to a source electrode.

A low concentration p-type diffusion layer 5 (p-type well region) and a low concentration n-type diffusion layer 6 (n-type offset region) are formed in a surface layer of a p-type silicon substrate 4 so that the low concentration n-type diffusion layer 6 is disposed apart from the low concentration p-type diffusion layer 5. A high concentration-type diffusion layer 7 (n-type source region) and a high concentration p-type diffusion layer 8 (p-type contact region) are formed in a surface layer of the low concentration p-type diffusion layer 5. A high concentration n-type diffusion layer 17 (n-type drain region) is formed in a surface layer of the low concentration n-type diffusion layer 6.

A LOCOS film 18 about 0.6 μm thick is formed in the surface of the p-type silicon substrate 4 so as to be in contact with the high concentration p-type diffusion layer 8 (p-type contact region). A LOCOS film 9 is formed in the surface of the p-type silicon substrate so as to be in contact with the high concentration n-type diffusion layer 17 (n-type drain region). It is preferable from the viewpoint of reliability that the thickness of the LOCOS film 18 is in a range of from 0.2 μm to 0.6 μm.

A gate electrode 11 is formed, through a gate insulating film 19 (e.g. a gate oxide film), on the low concentration p-type diffusion layer 5 and the p-type silicon substrate so as to extend from a region between the high concentration n-type diffusion layer 7 and the low concentration n-type diffusion layer 6 to a region above the LOCOS film 9.

The nitride film 14 is formed on a surface of the LOCOS film 18 so as to be in contact with the high concentration p-type diffusion layer 8. A BPSG film 10 about 0.6 μm thick is formed on the nitride film 14, the gate electrode 11 and the LOCOS film 9. Contact holes 20 are formed in the BPSG film 10. It is preferable from the viewpoint of reliability that the thickness of the BPSG film 10 is in a range of from 0.4 μm to 1 μm.

A source electrode 12 is formed on the BPSG film 10 through one of the contact holes 20 so as to be electrically connected to the high concentration n-type diffusion layer 7 and the high concentration p-type diffusion layer 8. A drain electrode 13 is formed on the BPSG film 10 through the other of the contact holes 20 so as to be electrically connected to the high concentration n-type diffusion layer 17.

Incidentally, the high concentration n-type diffusion layer 7 is an n-type source region, the high concentration n-type diffusion layer 17 is an n-type drain region, and the high concentration p-type diffusion layer 8 is a p-type contact region. Further, the low concentration p-type diffusion layer 5 is a p-type well region, and the low concentration n-type diffusion layer 6 is an n-type offset region.

When the thickness and refractive index of the nitride film 14 are set at predetermined values, the nitride film 14 can be provided as a semi-insulative thin film. Holes 31 produced in the LOCOS film 18 during γ-ray irradiation can be pulled out by a path 25 which extends from the nitride film 14 to the source electrode 12 via the high concentration p-type diffusion layer 8. As a result, the amount of plus fixed electric charges 33 stored in the LOCOS film 18 can be reduced greatly. More effectively, a contact hole not shown may be further effectively formed in the BPSG film 10 so that the nitride film 14 can be directly connected to the source electrode 12.

In this embodiment, the nitride film 14 having a thickness of 0.1 μm and a refractive index of 2.0 was formed between the LOCOS film 18 and the BPSG film 10. As a result, a withstand voltage drop of 13V was obtained compared with the case of no irradiation with radiation, so that the degree of the withstand voltage drop was suppressed compared with the background art. The level of leakage current was the same as in the background art.

Although the nitride film 14 having a refractive index of 2.0 was used in this embodiment, it is preferable that the refractive index is in a range of from 2.0 to 2.1, both inclusively. As the composition ratio of silicon increases (the nitride film 14 becomes rich in silicon), the refractive index of the nitride film 14 increases and the resistivity of the nitride film 14 decreases.

When the refractive index is lower than 2.0, the composition ratio of silicon becomes so low that the resistivity becomes high. As a result, the capability of pulling out holes 31 becomes so poor that plus fixed electric charges 33 are accumulated in the LOCOS film 18. In addition, the interfacial level increases. For this reason, both reduction in withstand voltage and increase in leakage current are induced.

On the other hand, when the refractive index is higher than 2.1, the composition ratio of silicon becomes too high so that the resistivity becomes too low. As a result, both reduction in withstand voltage and increase in leakage current are induced in the element.

When the nitride film 14 is selected in the aforementioned condition, the current which flows in the nitride film 14 as a semi-insulative thin film when a rating voltage is applied to the element can be set in a range of from 1 pA to 1 nA. That is, when the resistivity of the nitride film 14 is set so that the current which flows in the nitride film 14 when the rating voltage is applied is in a range of from 1 pA to 1 nA, the amount of plus fixed electric charges 33 accumulated in the LOCOS film 18 can be greatly reduced. More preferably, the current which flows in the nitride film 14 may be set in a range of from 1 pA to 100 pA.

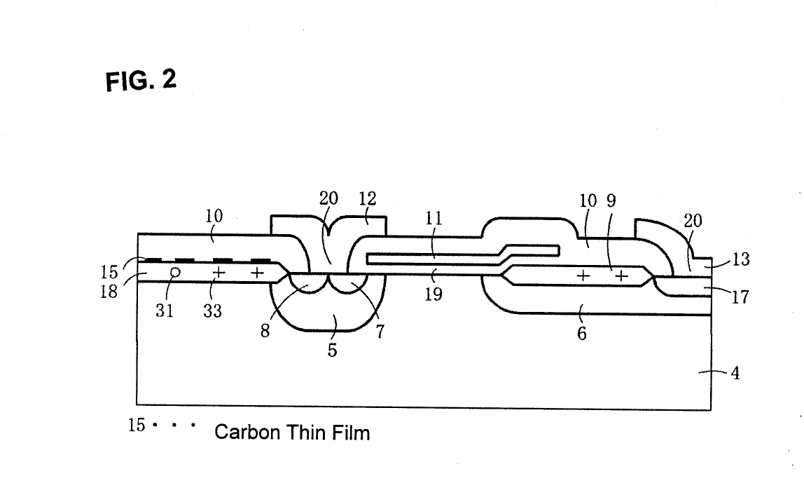

FIG. 2 is a sectional view showing important part of an MOS type semiconductor device according to a second embodiment of the invention. A MOSFET is taken as an example of the MOS type semiconductor device. The point of difference of FIG. 2 from FIG. 1B lies in that a carbon thin film 15 is used in place of the nitride film 14. The carbon thin film 15, which is preferably a conductive thin film having an average thickness of 0.1 nm, is formed between the LOCOS film 18 and the BPSG film 10. In this embodiment, the withstand voltage drop is 15V which is improved compared with the background art. The level of the leakage current is the same as in the background art. In this embodiment, the carbon thin film 15 is preferably formed by a sputtering method so that the average thickness of the carbon thin film 15 is 0.5 nm. Besides carbon, a high melting point metal such as tungsten, titanium or chromium may be used.

Because this type metal generally shows poor wetability with the LOCOS film 18, this type metal is shaped not like a film but like isolated particles so that a high resistivity can be achieved. Holes 31 are pulled out via a place (not shown) where carbon particles are connected to one another. The term “average thickness” means a height (thickness) on the assumption that all the isolated particles are spread evenly on the whole surface.

The average thickness of the carbon thin film 15 is set in a range of from 0.1 nm to 0.5 nm, both inclusively. When the average thickness of the carbon thin film 15 is set in this range, both prevention of reduction in withstand voltage and prevention of increase in leakage current can be achieved.

If the average thickness is smaller than 0.1 nm, fixed electric charges are accumulated in the LOCOS film 18 because the resistivity is too high so that holes 31 can hardly be pulled out from the LOCOS film 18. On the other hand, if the average thickness is larger than 0.5 nm, the leakage current of the element increases because the resistivity is too low.

Although a sputtering method is preferably used as a method of forming the thin film, an ion implantation method may be used in place of the sputtering method. The dose quantity of carbon may be preferably set in a range of from 5×10¹¹ atom/cm² to 1×10¹³ atom/cm². When the carbon thin film 15 is formed under this condition, the current which flows in the carbon thin film 15 when a rating voltage is applied is in a range of from 1 pA to 1 nA.

That is, when the resistivity of the carbon thin film 15 is set so that the current which flows in the carbon thin film 15 when a rating voltage is applied is in a range of from 1 pA to 1 nA, plus fixed electric charges 33 accumulated in the LOCOS film 18 can be reduced greatly. More preferably, the current which flows in the carbon thin film 15 may be set in a range of from 1 pA to 100 pA.

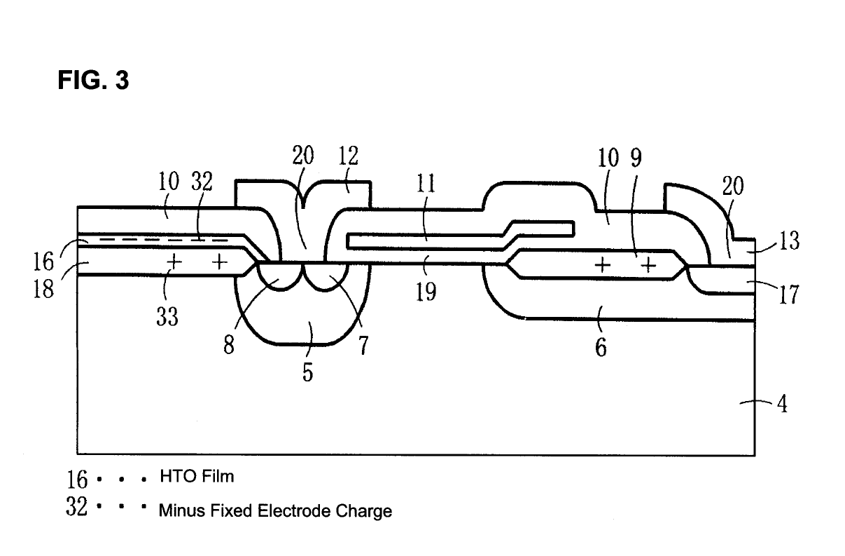

FIG. 3 is a sectional view showing important part of an MOS type semiconductor device according to a third embodiment of the invention. A MOSFET is taken as an example of the MOS type semiconductor device. The point of difference of FIG. 3 from FIG. 1B lies in that an insulative thin film for producing minus fixed electric field, such as an HTO (High Temperature Oxide) film 16, is used as an intermediate layer in place of the nitride film 14. Minus fixed electric field is produced under the presence of minus fixed electric charges 32 in the HTO film 16.

In this embodiment, the HTO film 16 which is an insulative thin film about 0.2 μm thick is formed between the LOCOS film 18 and the BPSG film 10. Because the HTO film 16 is apt to be negatively electrically charged after film-formation, minus fixed electric charges 32 can exist in the HTO film 16. As a result, fixed electric charges in the silicon interface made of a combination of the LOCOS film 18, the HTO film 16 and the BPSG film 10 can be set at a minus value so that plus fixed electric charges 33 in the LOCOS film 18 can be offset by the minus fixed electric charges in the silicon interface. As a result, the influence of the plus fixed electric charges 33 can be reduced.

In this embodiment, the withstand voltage drop is 20V which is improved compared with the background art. The thickness of the HTO film 16 which is an insulative thin film may be preferably set in a range of from 0.1 μm to 0.5 μm. If the thickness of the HTO film 16 is smaller than 0.1 μm, it is difficult to form the HTO film 16 by CVD. On the other hand, if the thickness is larger than 0.5 μm, it is difficult to form the HTO film 16 because the film cracks.

The level of the leakage current is the same as in the background art. When the HTO film 16 under this condition is selected, the current which flows in the HTO film 16 when a rating voltage is applied is in a range of from about 1 pA to about 1 nA. That is, when the thickness of the HTO film 16 is changed to obtain a proper resistivity so that the current which flows in the HTO film 16 when a rating voltage is applied is in a range of from 1 pA to 1 nA, the influence of plus fixed electric charges 33 in the LOCOS film 18 can be greatly reduced. More preferably, the current which flows in the HTO film 16 may be set in a range of from 1 pA to 100 pA.

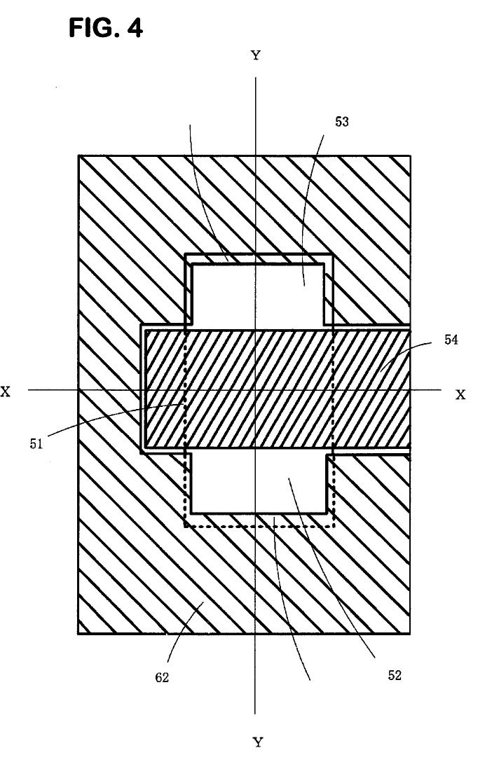

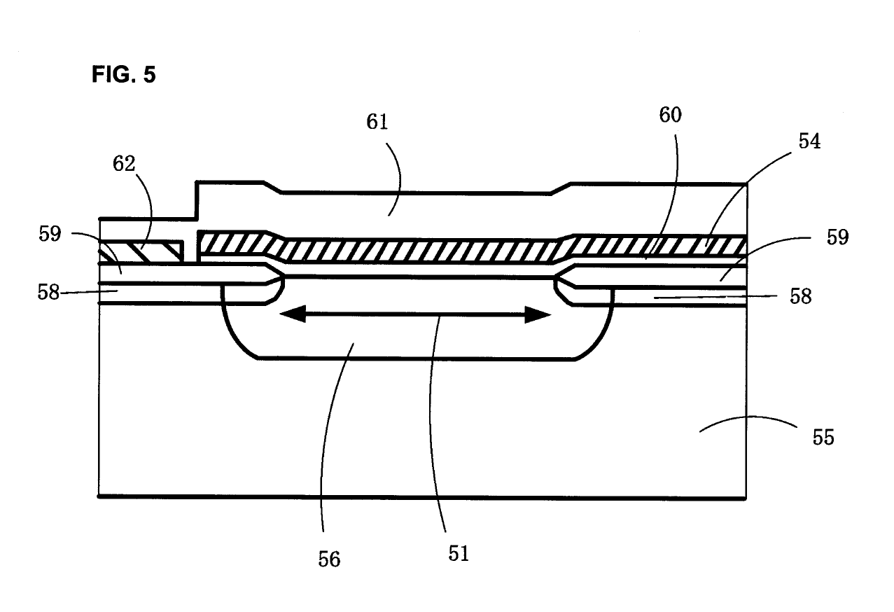

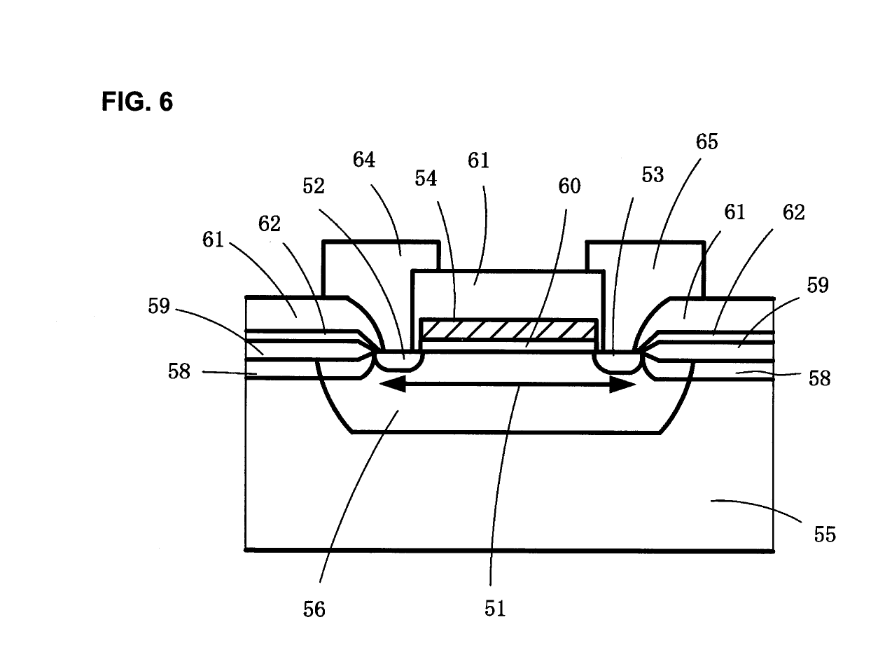

FIGS. 4 to 6 show the configuration of an MOS type semiconductor device according to a fourth embodiment of the invention. FIG. 4 is a plan view showing important part of the MOS type semiconductor device. FIG. 5 is a sectional view of important part, taken along the line X-X in FIG. 4. FIG. 6 is a sectional view of important part, taken along the line Y-Y in FIG. 4. An MOSFET is taken as an example of the MOS type semiconductor device. In this embodiment, a semi-insulative nitride film 62 (which is the same as the nitride film 14 described with reference to FIGS. 1A and 1B) is used as a semi-insulative thin film. The semi-insulative nitride film 62 is formed on an LOCOS film 59. Particularly preferably, the semi-insulative nitride film 62 is formed so as to be adjacent to a gate electrode 54. In this embodiment, the periphery (hereinafter referred to as “gate peripheral portion”) of an end portion of the gate electrode 54 is surrounded by the semi-insulative nitride film 62. A middle concentration p-type diffusion layer 58 is formed under the LOCOS film 59.

FIG. 4 shows a simplified planar structure of an n-type MOSFET as a constituent member of an integrated circuit. As shown in FIG. 4, a source region 52 and a drain region 53 are disposed in an active region 51 while the gate electrode 54 is disposed straddling the active region 51. The LOCOS film 59, a source electrode 64 and a drain electrode 65 are not shown in FIG. 4.

In FIGS. 5 and 6, the n-type MOSFET includes a p-type diffusion layer 56 formed in a p-type silicon substrate 55 and higher in impurity concentration than the p-type silicon substrate 55, a source region 52 formed as a high concentration n-type diffusion layer, a drain region 53 formed as a high concentration n-type diffusion layer, a source electrode 64 formed on the source region 52, and a drain electrode 65 is formed on the drain region 53.

The n-type MOSFET further includes a middle concentration p-type diffusion layer 58 (e.g. with an impurity concentration of about 1×10¹⁷cm⁻³) selectively formed in a surface layer of the p-type diffusion layer 56 and higher in impurity concentration than the p-type diffusion layer 56 but lower in impurity concentration than the source region 52 and the drain region 53, an LOCOS film 59 surrounding the active region 51, and a semi-insulative nitride film 62 formed on the LOCOS film 59 of the gate peripheral portion so as to be in contact with the source region 52 and the drain region 53 at a contact portion. The semi-insulative nitride film 62 is electrically connected to the source electrode 64 through the source region 52 and electrically connected to the drain electrode 65 through the drain region 53.

The n-type MOSFET further includes a gate insulating film 60 (e.g. a gate oxide film) formed on the p-type diffusion region 56 so as to be located between the source region 52 and the drain region 53, a gate electrode 54 formed on the gate insulating film 60, and a protective film 61 formed as an insulating film with which the gate electrode 54 is covered. The gate electrode 54 extends to the outside of the active region 51 and serves also as gate wiring.

After a polysilicon film 0.6 μm thick is formed so that the polysilicon film will serve as the gate electrode 54, a semi-insulative nitride film 62 having a thickness of 0.1 μm and a refractive index of 2.0 is formed on the LOCOS film 59. Then, a 1 μm-thick protective film 61 is formed on the semi-insulative nitride film 62 in such a manner that an HTO film and a BPSG film are laminated successively as the protective film 61. The protective film 61 may be replaced by a BPSG film as described in the first to third embodiments or may be replaced by another insulating film. In the first to third embodiments, the protective film 61 described in this embodiment or another insulating film may be used in place of the BPSG film 10. As described above, the semi-insulative nitride film 62 is connected to the source region 52 and the drain region 53 at the contact portion. Incidentally, the semi-insulative nitride film 62 may be connected to only the source region 52.

Because the semi-insulative nitride film 62 is connected to the source region 52 as described above, holes produced in the LOCOS film 59 by radiation move rapidly to the source region 52 through the semi-insulative nitride film 62. Accordingly, plus electric charges are not accumulated in the LOCOS film 59.

A 0.1 nm-thick carbon thin film or the like may be used in place of the semi-insulative nitride film 62. The same effect can be also obtained when a 0.5 nm-thick carbon thin film formed as a conductive thin film by a sputtering method is used. It is therefore preferable that the thickness of the carbon thin film is set in a range of from 0.1 nm to 0.5 nm, both inclusively, when the carbon thin film is used. When ion implantation is used for forming the carbon thin film, the dose quantity (implant doze) of carbon may be set in a range of from 5×10¹¹ atom/cm² to 1×10¹³ atom/cm². When the carbon thin film is formed under this condition, the current which flows in the carbon thin film when a rating voltage is applied is in a range of from about 1 pA to about 1 nA. More preferably, the current which flows in the carbon thin film may be set in a range of from 1 pA to 100 pA.

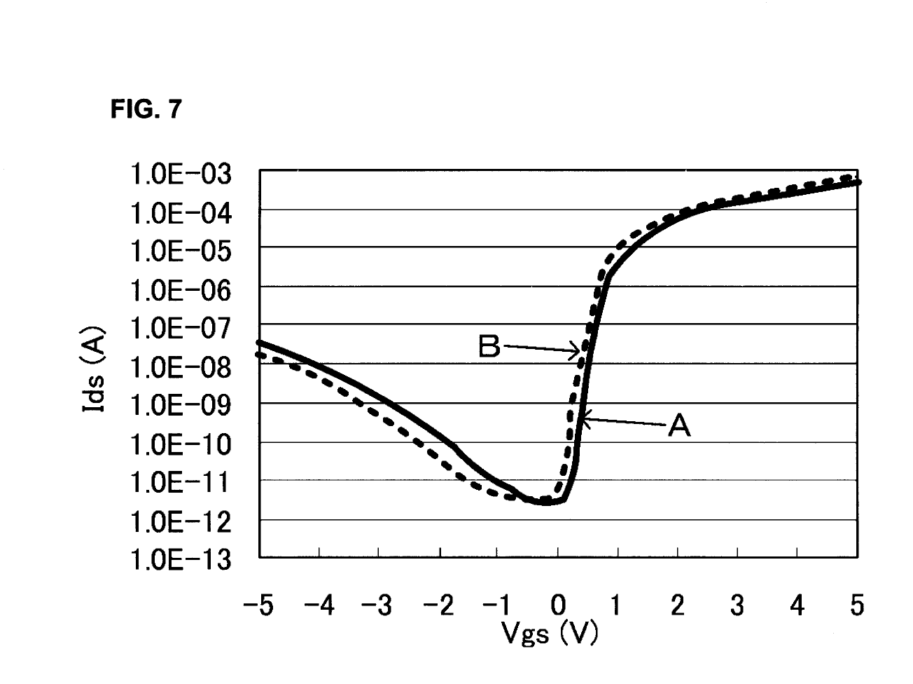

Besides carbon, a high melting point metal such as tungsten, titanium or chromium may be used for forming the conductive thin film. Because this type metal generally shows poor wettability with an insulating film such as the LOCOS film 59, this type metal is shaped not like a film but like isolated particles so that a high resistivity can be achieved. When an ion implantation method is used in this case, the dose quantity of this type metal may be set in a range of from 5×10¹¹ atom/cm² to 1×10¹³ atom/cm². When the thin film is formed under this condition, the current which flows in the thin film when a rating voltage is applied is in a range of from about 1 pA to about 1 nA. More preferably, the current which flows in the thin film may be set in a range of from 1 pA to 100 pA. FIG. 7 is a graph showing the threshold characteristic of the NMOSFET before and after irradiation with radiation using cobalt-60 as a γ-ray source. In FIG. 7, a semi-insulative nitride film 62 having a thickness of 0.1 μm and a refractive index of 2.0 is used as the semi-insulative thin film.

After irradiation (broken line B), the threshold voltage decreases by 60 mV like the background art but the level of the leakage current is substantially equal to the initial value (solid line A) and improved greatly compared with the background art. The withstand voltage of the MOSFET is 12.0V. In this embodiment, a nitride film having a refractive index of 2.0 is used as the semi-insulative nitride film 62. The range of the refractive index is the same as described with reference to FIGS. 1A and 1B. That is, the refractive index of the semi-insulative nitride film 62 may be set in a range of from 2.0 to 2.1, both inclusively. When the semi-insulative nitride film 62 is formed under this condition, the current which flows in the semi-insulative nitride film 62 when a rating voltage is applied is in a range of from about 1 pA to about 1 nA. More preferably, the current which flows in the semi-insulative nitride film 62 may be set in a range of from 1 pA to 100 pA.

The same effect can be also obtained when a carbon thin film is used in place of the semi-insulative nitride film 62.

When the invention is applied, electric charges can be prevented from being accumulated in these gate peripheral portions. Accordingly, improvement in radiation characteristic can be attained without both increase in leakage current and reduction in withstand voltage.

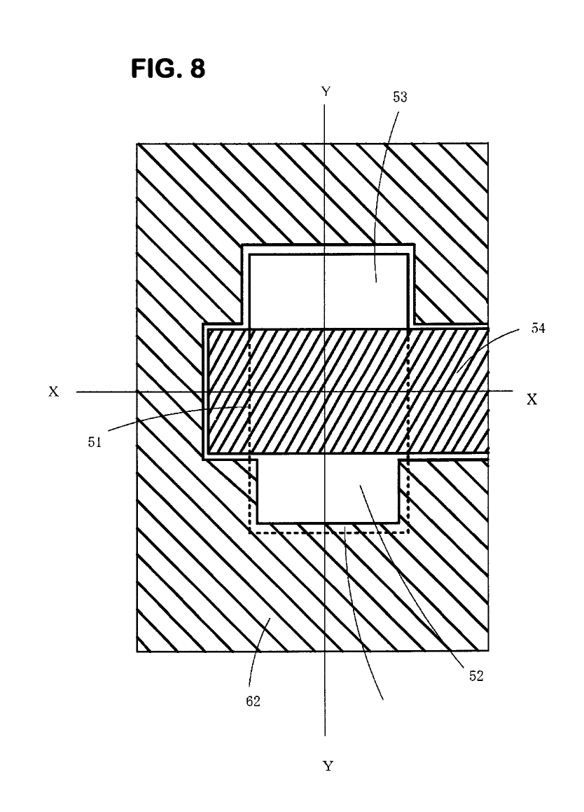

FIG. 8 is a plan view showing important part of an MOS type semiconductor device according to a fifth embodiment of the invention. The fifth embodiment has the same configuration as the fourth embodiment except that the semi-insulative nitride film 62 is connected only to the source region 52. The same effect as in the fourth embodiment can be obtained by the fifth embodiment.

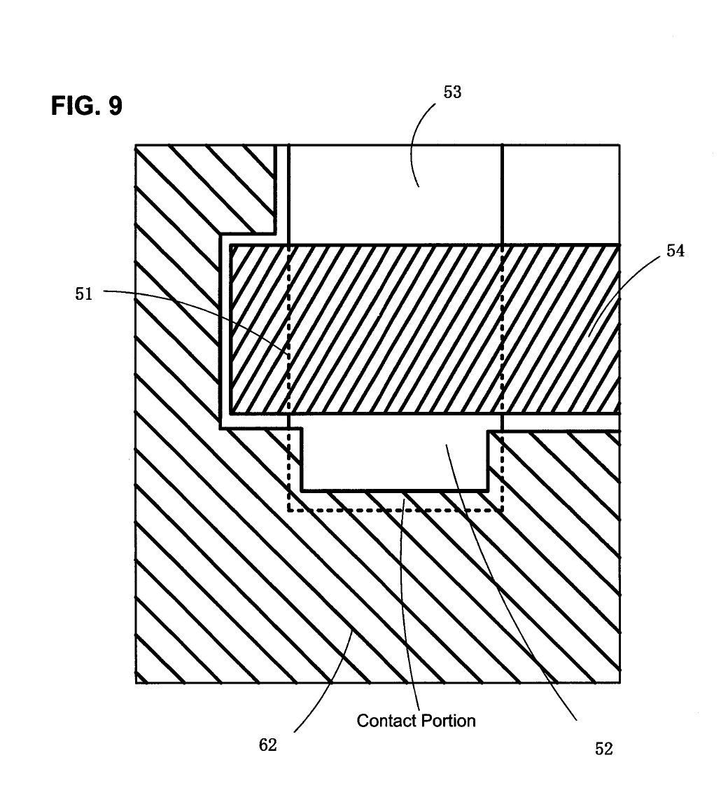

FIG. 9 shows a modification of FIG. 8, that is, shows the case where part of the periphery of the drain region 53 is not covered with the semi-insulative nitride film 62. The same effect as in FIG. 8 can be obtained in this case if the gate peripheral portion is covered with the semi-insulative nitride film 62 so as to be electrically connected to the source region 52.

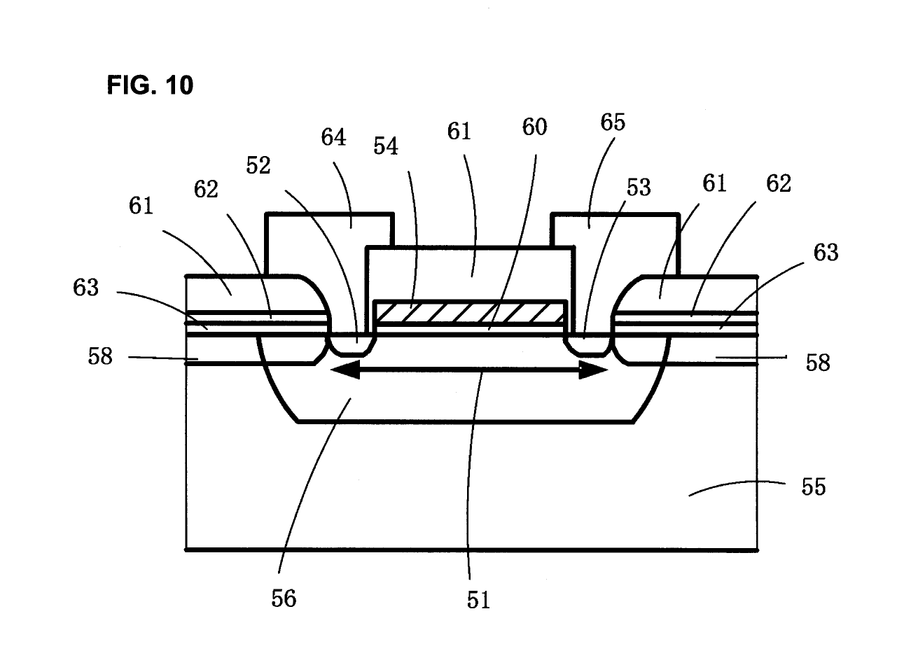

FIG. 10 is a sectional view showing important part of an MOS type semiconductor device according to a sixth embodiment of the invention. FIG. 10 is a sectional view like FIG. 6 showing the fourth embodiment. A plan view is the same as in the fourth embodiment and description thereof will be omitted. The point of difference between the sixth embodiment and the fourth embodiment lies in that the LOCOS film 59 formed under the semi-insulative nitride film 62 is replaced by a thermal oxide film 63. In this case, the semi-insulative nitride film 62 is directly connected to a source electrode 64 and a drain electrode 65. In addition, a protective film 61 (inclusive of an interlayer insulating film) is formed on the gate electrode 54.

The thermal oxide film 63 to be formed under the semi-insulative nitride film 62 is formed in such a manner that a thick oxide film is formed on the whole area of a silicon surface by exposing the silicon surface to a high temperature in an atmosphere of steam and then the thick oxide film is patterned. The LOCOS films 9 and 18 are thick oxide films which are selectively formed when the silicon surface masked with the nitride film is exposed to a high temperature in an atmosphere of steam. The same effect as described in the first to third embodiments can be also obtained when the LOCOS films 9 and 18 in first to third embodiments are replaced by the thermal oxide films 63.

Although the embodiments have been described on the case where an MOSFET is taken as an example, the invention can be applied to a device having an insulated gate structure (MOS type gate structure) such as an IGBT. For example, the IGBT can be configured when the high concentration n-type diffusion layer 17 in the MOSFET shown in FIGS. 1A and 1B is replaced by a high concentration p-type diffusion layer.

The invention has been described with reference to certain preferred embodiments thereof. It will be understood, however, that modifications and variations are possible within the scope of the appended claims.

This application is based on, and claims priority to, Japanese Patent Application No. 2008-156099, filed on Jun. 16, 2008 and Japanese Patent Application No. 2009-090001, filed on Apr. 2, 2009. The disclosure of the priority applications, in their entirety, including the drawings, claims, and the specifications thereof, are incorporated herein by reference.

What is claimed is:

1. An MOS type semiconductor device comprising:
a semiconductor substrate;
an insulating film disposed on the semiconductor substrate; and
a thin film disposed on the insulating film so as to be lower in resistivity than the insulating film,
wherein the thin film is electrically connected to a source electrode.

2. The MOS type semiconductor device according to claim 1, wherein the insulating film is one of a LOCOS film and a thermal oxide film.

3. The MOS type semiconductor device according to claim 1, wherein the thin film is disposed so that a source portion and a drain portion disposed on the semiconductor substrate to form the MOS type semiconductor device are surrounded by the thin film.

4. The MOS type semiconductor device according to claim 1, wherein the thin film has such a resistivity that a current of 1 pA to 1 nA flows when a rating voltage is applied between the source electrode and the drain electrode.

5. The MOS type semiconductor device according to claim 4, wherein the thin film is a semi-insulative thin film.

6. The MOS type semiconductor device according to claim 5, wherein the semi-insulative thin film is one of a nitride film and a film capable of producing negative fixed electric charges and has a refractive index of 2.0 to 2.1.

7. The MOS type semiconductor device according to claim 4, wherein the thin film is a conductive thin film.

8. The MOS type semiconductor device according to claim 7, wherein the conductive thin film is one of a carbon thin film and a high melting point metal thin film and has an average thickness of 0.1 nm to 0.5 nm.

9. The MOS type semiconductor device according to claim 8, wherein the high melting point metal thin film is any one of a tungsten thin film, a titanium thin film and a chromium thin film.

10. The MOS type semiconductor device according to claim 1, wherein a second insulating film higher in resistivity than the thin film is formed on the insulating film through the thin film.

11. An MOS type semiconductor device comprising:
a semiconductor substrate;
an insulating film disposed on the semiconductor substrate; and
a thin film disposed on the insulating film so as to be lower in resistivity than the insulating film,
wherein the thin film is electrically connected to a source electrode or to both the source electrode and a drain electrode.

12. The MOS type semiconductor device according to claim 11, wherein the insulating film is one of a LOCOS film and a thermal oxide film.

13. The MOS type semiconductor device according to claim 11, wherein the thin film is disposed so that a source portion and a drain portion disposed on the semiconductor substrate to form the MOS type semiconductor device are surrounded by the thin film.

14. The MOS type semiconductor device according to claim 11, wherein the thin film has such a resistivity that a current of 1 pA to 1 nA flows when a rating voltage is applied between the source electrode and the drain electrode.

15. The MOS type semiconductor device according to claim 14, wherein the thin film is a semi-insulative thin film.

16. The MOS type semiconductor device according to claim 15, wherein the semi-insulative thin film is one of a nitride film and a film capable of producing negative fixed electric charges and has a refractive index of 2.0 to 2.1.

17. The MOS type semiconductor device according to claim 14, wherein the thin film is a conductive thin film.

18. The MOS type semiconductor device according to claim 17, wherein the conductive thin film is one of a carbon thin film and a high melting point metal thin film and has an average thickness of 0.1 nm to 0.5 nm.

19. The MOS type semiconductor device according to claim 18, wherein the high melting point metal thin film is any one of a tungsten thin film, a titanium thin film and a chromium thin film.

20. The MOS type semiconductor device according to claim 11, wherein a second insulating film higher in resistivity than the thin film is formed on the insulating film through the thin film.
